(19) United States
(12) Patent Application Publication
(10) Pub. No.: US 2005/0053852 A1
(43) Pub. Date: Mar. 10, 2005

(54) Method of fabricating substrate with color filter

(75) Inventor: Chi-Ming Cheng, Tainan City (TW)

Correspondence Address: LIU & LIU, 811 WEST SEVENTH STREET, SUITE 1100, LOS ANGELES, CA, 90017, US

(73) Assignee: Toppoly Optoelectronics Corp.

(21) Appl. No.: 10/773,624

(22) Filed: Feb. 6, 2004

(30) Foreign Application Priority Data
Sep. 9, 2003 (TW) 92124846

(51) Int. Cl. G03F 9/00

(52) U.S. Cl. 430/7

(57) ABSTRACT

A method of fabricating a color filter substrate for a transflective LCD panel. A color filter is formed on a substrate with pre-defined reflective and transmissive areas, comprising a color filter layer having opening portions. A flat layer is formed to cover the color filter and fill the opening portions. The flat layer and the color filter are planarized (e.g., by polishing) to provide a flat surface. Subsequent processing may include an electrode layer formed on the surface of the color filter to complete the color filter substrate.

### BACKGROUND OF THE INVENTION

1. Field of the Invention

The present invention relates to a method of fabricating a substrate with color filter for a liquid crystal display (LCD), and in particular to a method for fabricating a transflective color filter substrate.

2. Description of the Related Art

A typical transflective liquid crystal display has transmissive and reflective regions, and is composed by upper and lower substrates with liquid crystal filled therebetween. The upper substrate (in reference to a user's viewpoint) is typically known as a color filter substrate and the lower substrate is an array substrate. Various methods for fabricating transflective color filter substrates, include pigment diffusion, gelatin dyeing, printing, and electrodeposition. Conventionally, there are areas (generally referred herein as reflective areas) defined on a color filter substrate, which allows light (e.g., ambient light) to pass through the color filter substrate to the liquid crystal layer, which are then reflected at certain areas on the array substrate back through the color filter substrate. The reflective areas are usually blank areas or openings in the R, G, and B colored resists disposed on a color filter substrate.

One conventional approach of fabricating a transflective color filter substrate is to blanketly cover the color filter supported substrate with a transparent photoresist material. FIGS. 1A and 1B show a conventional fabrication process of a transflective color filter substrate 1 by a pigment diffusion method. In FIG. 1A, a substrate 10, i.e. an upper substrate or a special substrate for use as a color filter, is pre-defined with a reflective area and a transmissive area (generally the colored portions through which light is filtered) corresponding to certain reflective and transmissive area on an array substrate (not shown), i.e. a lower substrate. Color filters formed on the substrate 10, include regions of red, green, and blue resists 12 (i.e., colored photoresists), opening regions 14, and black matrices 16, fabricated by a conventional pigment diffusion method and photolithography process. In FIG. 1B, a transparent resist 18 is blanketly deposited by spin coating over the surface of the substrate 10, substantially filling the opening regions 14. As a result, the color resists 12, black matrices 16 and opening regions 14 are covered and filled with the transparent resist 18 and no further exposure proceeds. Blanketly coating the transparent resist, however, usually results in a high viscosity resist, which leaves particles, e.g. small solid pieces or holes/air pockets in the resist, during the process and/or results in muras formation (i.e., local or large area non-uniformity over the whole screen of an LCD), thus reducing yield.

In the conventional approach, an additional photolithography process is used. FIGS. 1C and 1D show the conventional fabrication process succeeding FIG. 1B. In FIG. 1C, after the transparent resist 18 is blanketly deposited, photolithography 22 is performed using a mask 20 to expose the transparent resist 18 on top of opening regions 14 only. The unexposed transparent resist 18 is then developed and removed, leaving exposed resists in the opening regions 14, thus forming a color filter substrate 1 (there may be additional layers not shown in FIG. 1D which are required to complete the color filter substrate) as shown in FIG. 1D. It is noted that the removal of the unexposed transparent resist 18 does not result in a smooth, flat surface. For example, the exposed photoresists at opening regions 14 may protrude above the neighboring color filters 12. Further, any differences in thickness in the color filter portions 12 could potentially further create unevenness in the final surface of the color filter substrate. The selective formation of transparent resists in the opening regions 14 requires an additional photolithography process, thus increasing production cost, and introducing remnant particles in the final structure. Such particles, and the resultant uneven surface reduce overall yield of the fabrication process.

### SUMMARY OF THE INVENTION

The present invention provides a method of fabricating a color filter substrate which includes planarization of the color filter layer.

In one embodiment of the invention the excess transparent photoresist over the R, G, and B resists of the color filter is planarized by polishing, instead of removed by conventional photolithography process. Particles of remnant transparent resist are also removed by polishing and thereby increasing yield and obtaining a flat surface. Moreover, the flat surface formed by polishing also prevents height difference between R, G, and B colored resists from occurring during panel assembly, thus improving the optical properties of the finished display device.

In one embodiment, the present invention provides a method for fabricating a transflective color filter substrate. In an embodiment, a color filter is formed on a substrate with pre-defined reflective and transmissive areas, comprising color, opening and light-blocking portions. A flat layer is formed to cover the substrate and fill the opening portion. The flat layer is then polished to provide a flat surface. Finally, an electrode layer is formed above on the surface of the color filter.

In another aspect, the present invention provides a method for fabricating a liquid crystal display that comprises a lower array substrate and an upper color filter substrate. The present invention is also directed to a novel color filter substrate, and a liquid crystal display having a color filter substrate of the present invention.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1A to 1D are schematic sectional views illustrating a conventional process of fabricating a transflective color filter substrate;

FIGS. 2A to 2E are schematic sectional views illustrating the process flow of fabricating a transflective color filter substrate in accordance with one embodiment of the invention;

FIG. 3 is a schematic drawing showing a liquid crystal panel comprising the transflective color filter shown in FIG. 2E in accordance with another embodiment of the invention;

FIG. 4 is a schematic drawing showing a liquid crystal device comprising the liquid crystal panel shown in FIG. 3 in accordance with another embodiment of the invention; and

FIG. 5 is a schematic drawing showing an electronic device comprising the liquid crystal device shown in FIG. 4 in accordance with another embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

It is noted that the description hereinbelow refers to various layers arranged on, above or overlying other layers, to describe the relative positions of the various layers. References to “on”, “above”, “overlying”, or other similar languages, are not limited to the interpretation of one layer being immediately adjacent another layer. There may be intermediate or interposing layers, coatings, or other structures present, and associated process steps present, which are not shown or discussed herein, but could be included without departing from the scope and spirit of the invention disclosed herein. Similarly, references to structures adjacent, between or other positional references to other structures merely describe the relative positions of the structures, with or without intermediate structures.

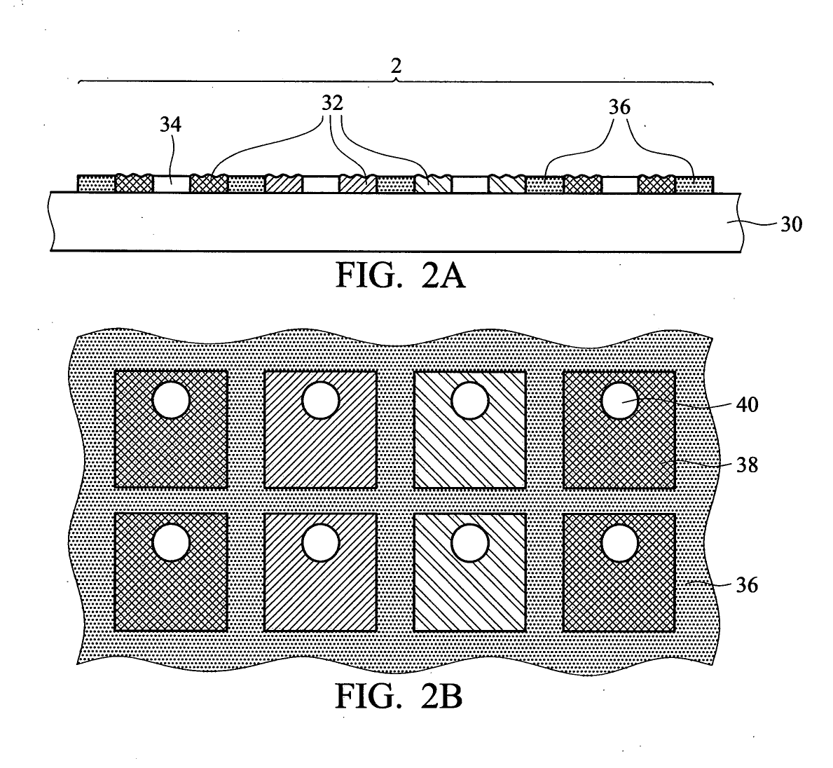

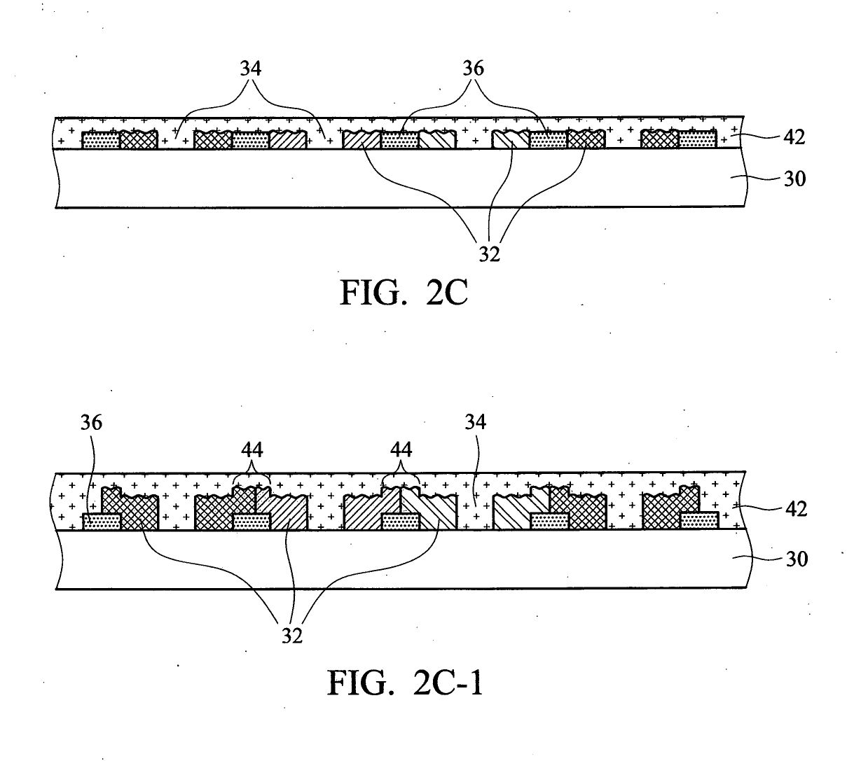

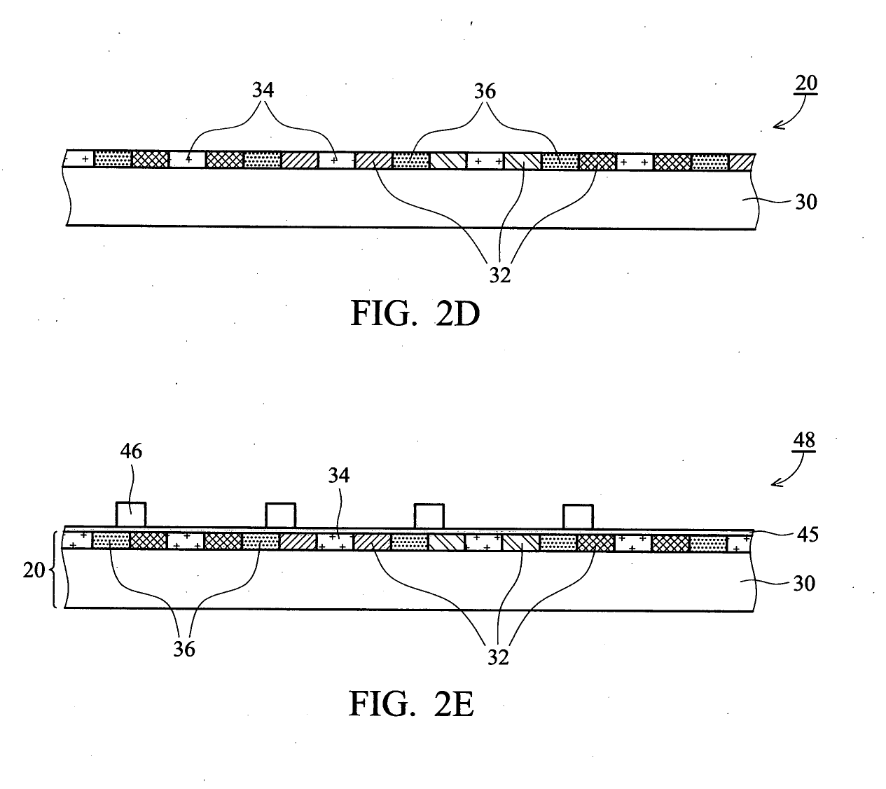

FIGS. 2A to 2E illustrate a flow of fabricating a transflective color filter 48 also known as an upper substrate in a liquid crystal display, in accordance with one embodiment of the invention. It is noted that the figures schematically illustrates only a section of the color filter substrate 20 that represents one pixel (FIG. 2B represents 2 pixels), which may be extended to many pixels.

As shown in a side view of FIG. 2A and a top view of FIG. 2B, a substrate 30, preferably a transparent and insulating substrate, is utilized to support a color filter layer 2 that defines reflective areas and transmissive areas, corresponding to certain reflective and transmissive areas on the array substrate, also known as a lower substrate. In the disclosed embodiment, the color filter layer 2 comprises R, B and G colored portions 32, a light-blocking portion 36, for example, black matrix, and an opening portion 34 is formed on the substrate 30. The R, B and G colored portions 32 define the transmissive area 38 on the substrate 30 and the opening portion 34 define reflective area 40 on the substrate 30, as shown in FIG. 2B.

The preferred light-blocking portion 36, for example, black matrix, comprises metal chromium or black resin, which is formed prior to the color portion 32. In an embodiment, black resin having a thickness of 1.2 μm is formed by photolithography. The preferred black resin is a mixed carbon acrylic polymer. In another embodiment, metal chromium having a thickness of 0.15 μm is also formed by photolithography. The color portions 32 are formed by spin-coating red, blue and green photoresists. In an embodiment, a red resist layer is spin-coated on the surface of the substrate 30. The red resist is subsequently defined by photolithography. The undefined red resist is removed to define a red portion having a thickness of about 1.7 μm on the pre-determined red pixel area of the substrate 30. The green and blue resists having a thickness of about 1.7 μm each are formed by repeating the previous steps.

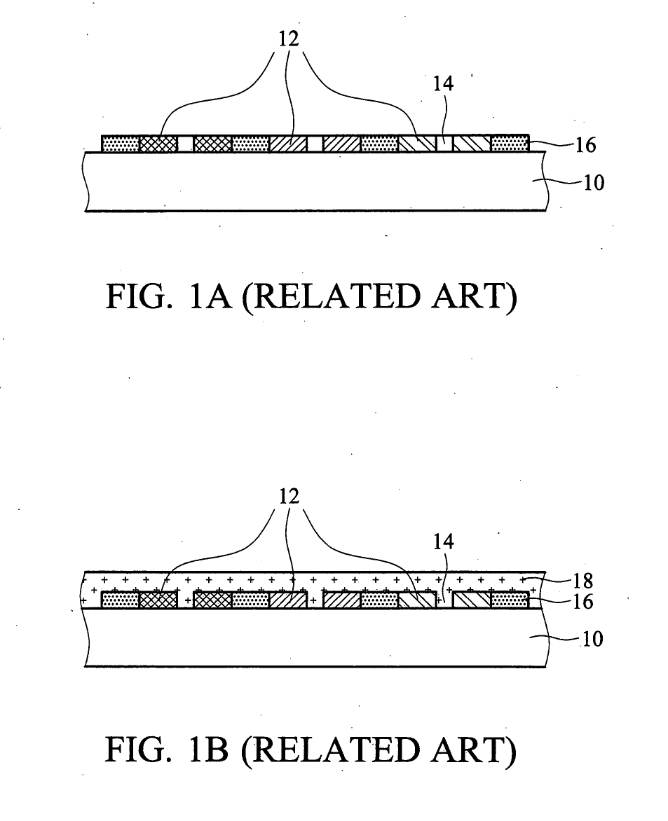

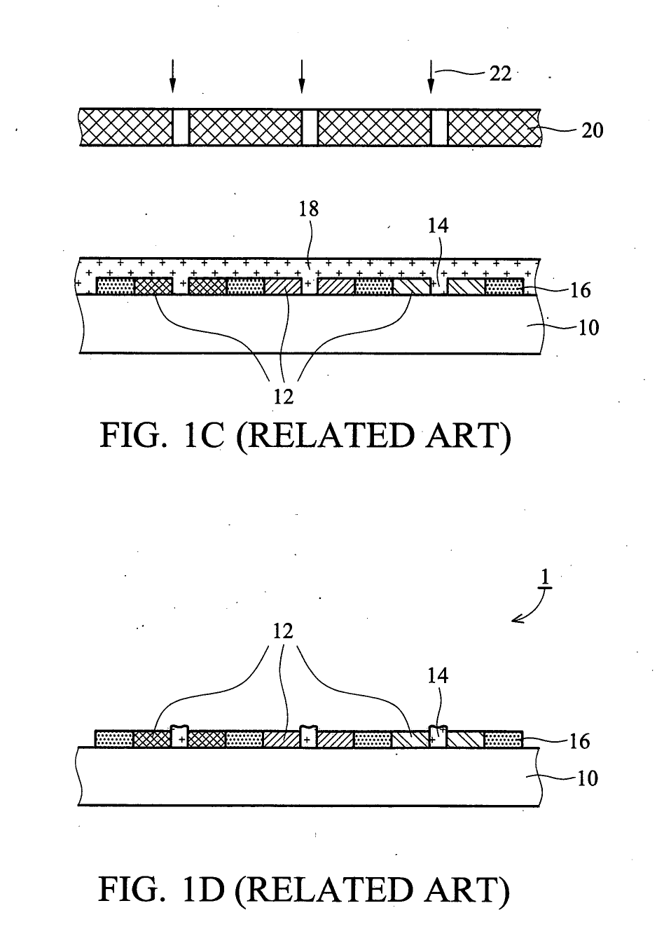

In an alternate embodiment, the R, G, and B colored portions may overlap the thinner light blocking portion 36 (e.g. metal chromium), as shown in FIG. 2C-1. In this alternate embodiment, a thin layer of light blocking portion 36 may be used, and the colored portions 44 provide a filler above the thin light blocking portion 36. When the colored portions 44 are planarized, a flat even surface is obtained, without exposing the underlying light blocking portions 36. Without the colored portions 44, the adjacent colored portions 32 would have to be planarized to the same thickness as the thin blocking portions 36, which may be prohibitive because the colored portion may be required to be maintained at a minimum thickness that is above the blocking portions 36 for their intended optical properties as color filter elements. If without the colored portion 44 above the blocking portions 36, a flat even surface would not be obtained in order to maintain the required thickness of the colored portions 32.

In an alternate embodiment, the R, G, and B colored portions may overlap the thinner light blocking portion 36 (e.g. metal chromium) due to low resolution or miss-aligned photolithography. The colored portions 44 as shown in FIG. 2C-1 stack on the blocking portions 36, which cause a height difference between the colored portions 44 and the the adjacent colored portions 32.

In FIG. 2C, a filler layer 42 is formed by spin-coating, filling the opening portion 34 and covering the surface of the substrate 30. The preferred thickness of the filler layer 42 is over 5 μm. The preferred filler layer 42 is a transparent photoresist, a transparent light-sensitive material or a heat sensitive material. In FIG. 2C-1, the layer 42 is similarly formed.

In FIG. 2D, the filler layer 42 is polished until the surface of the color portions 32 are exposed, thereby removal of the filler layer 42 on top of the R, G, and B colored portions. Preferably polishing is anisotropic polishing, such as chemical mechanical polishing (CMP), as it provides quicker and simpler removal of the thick film. After anisotropic polishing, the thickness of the filler layer 42 filling in the opening portions 34 is equal to the thickness of the R, G, and B colored portions 32, and therefore a flat surface is achieved as shown in FIG. 2D. The particles of the filler layer 42 are also removed by polishing, thereby increasing yield.

In FIG. 2D, further polishing planarizes the exposed color portions 32 with respect to the resist-filled open portions 34. If the R, G, and B colored portions 44 overlap as shown in FIG. 2C-1, blanket polishing will planarize the color portions 44 to prevent height difference between R, G, and B colored resists.

In FIG. 2E, subsequent processing may include forming an electrode layer 45 on the surface of the colored filter substrate 20 (e.g., by sputtering). The preferred electrode layer 45 is a transparent conductive film, such as an indium tin oxide (ITO) film. Subsequent processing may include covering the electrode layer 45 with a negative photoresist layer (not shown), such as an acrylic material (e.g., by spin-coating). A photolithography process defines the negative photoresist layer to form resin pillars between the upper and lower substrates to act as spacers 46, forming a gap for liquid crystal. This completes the color filter 48 in accordance with the above-described embodiment of the present invention. As shown in FIG. 2E, since the color filter substrate 20 has a flat surface, spacers 46 with uniform thickness are also achieved. When used, the color filter substrate 20 (being the upper substrate) is turned upside down, with the spacers 46 towards the liquid crystal layer and array substrate (lower substrate).

According to the present invention, the excess flat layer on top surface of the R, G, and B colored resists 32 is removed by polishing, rather than photolithography. The particles of the filler layer 42 are also removed, thereby increasing yield. The flat layer can further be polished until the top surface of the R, G, and B colored resists are planarized and form a flat surface, thereby preventing color resist overlap and height difference. The transparent conductive film 45 would be deposited on an underlying even flat surface. The optical properties of the transflective color filter substrate are thus improved.

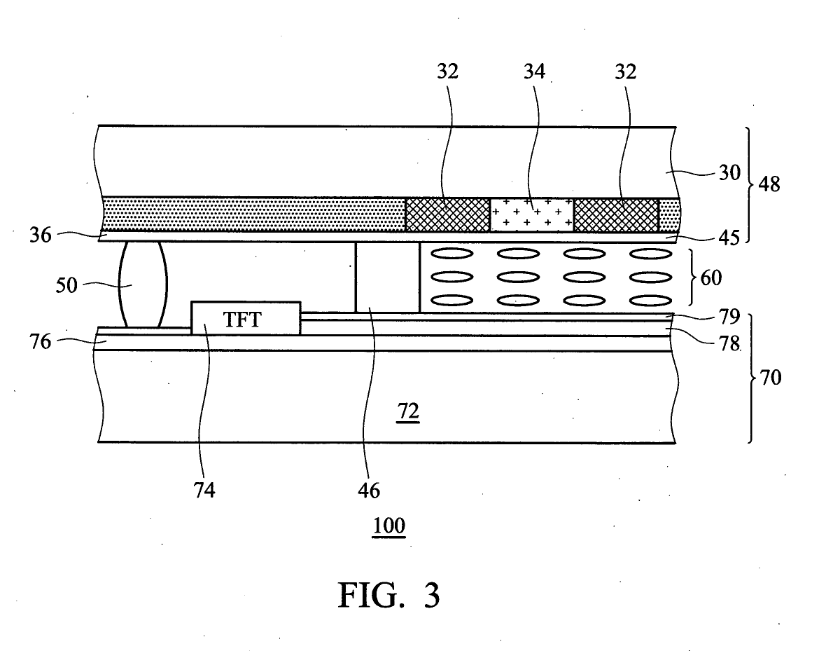

FIG. 3 is a schematic drawing showing a liquid crystal panel comprising the transflective color filter shown in FIG. 2E in accordance with another embodiment of the invention. A liquid crystal panel 100 comprises a color filter 48, which is formed in accordance with FIGS. 2A to 2E, an array substrate 70, and a liquid crystal display element 60 which is assembled between the color filter 48 and the array substrate 70. The array substrate 70 can be a conventional TFT array substrate, which comprises as glass substrate 72, a polarizer 76 on the glass substrate 72, and a TFT array 74 and an insulating layer 78 and a pixel electrode, e.g. ITO, disposed on the polarizer 76. The two glass substrates 70 and 48 can be assembled with a sealant 50, the gap between them is maintained by spacers 46, and liquid crystal material 60 is injected into the gap between the substrates.

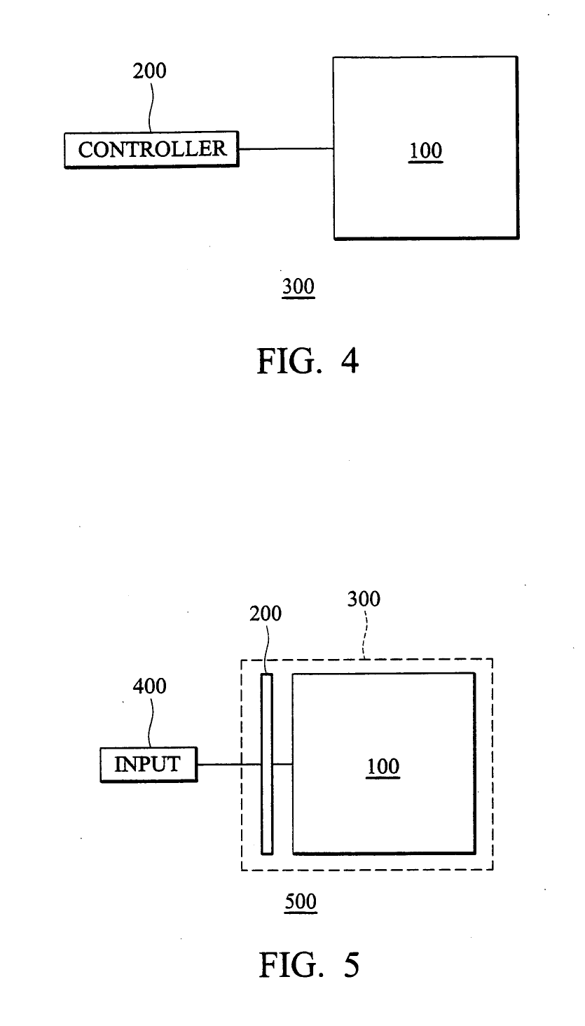

FIG. 4 is a schematic drawing showing a liquid crystal device comprising the liquid crystal panel shown in FIG. 3 in accordance with another embodiment of the invention. The liquid crystal panel 100 as shown in FIG. 3 is coupled to a controller 200 to form a liquid crystal device 300. The controller 200 can comprise a source and gate driving circuits (not shown) to control the liquid crystal panel to render image in accordance with an input.

FIG. 5 is a schematic drawing showing an electronic device comprising the liquid crystal device shown in FIG. 4 in accordance with another embodiment of the invention. An input device 400 is coupled to the controller 200 of the liquid crystal device 300 shown in FIG. 4 to form an electronic device 500. The input device 400 can comprise a processor or the like to input data to the controller 200 to render an image. The electronic device 500 can be any portable electronic devices such as PDA, cell phone, portable computer, mobile entertainment device, or non-portable device such as desktop computing devices.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). For example, the various steps for forming various structures described above may be substituted with different proceses (e.g., spin coating of photoresist layers may be substituting with another type coating process) Therefore, the scope of the appended claims should be accorded the broadest interpretation so as to encompass all such modifications and similar arrangements.

1. A method of fabricating a substrate with color filter, comprising the steps of:
(a) providing a substrate;
(b) forming a color filter above the substrate, wherein the color filter comprises opening portions;
(c) filling the opening portions in the color filter; and
(d) planarizing the color filter.

2. The method as claimed in claim 1, wherein the step of forming the color filter comprises the step of forming color portions adjacent to the opening portions, wherein the planarizing step comprises planarizing the colored portions with respect to the filled opening portions.

3. The method as claimed in claim 2, wherein the color filter substrate is of the transflective type, and wherein the colored portions and the opening portions correspond to transmissive areas and reflective areas of the color filter substrate respectively.

4. The method as claimed in claim 2, wherein the step of forming the color portions comprises the steps of spin-coating color photoresists and applying lithographic process to define the color portions.

5. The method as claimed in claim 2, wherein the filling step comprises the step of forming a layer of transparent material over the colored portions and filing the opening portions, and wherein the planarizing step comprises planarizing the colored portions with respect to the opening portions.

6. The method as claimed in claim 5, wherein the step of forming the layer comprises the step of spin-coating.

7. The method as claimed in claim 5, wherein the layer comprises one of a transparent resist material, a transparent light-sensitive material and a heat sensitive material.

8. The method as claimed in claim 1, further comprising the step of forming an electrode layer overlying above the color filter.

9. The method as claimed in claim 8, wherein the electrode layer is a transparent conductive film.

10. The method as claimed in claim 9, further comprising the step of forming a plurality of spacers on the electrode layer.

11. The method as claimed in claim 10, wherein the spacers are formed, comprising the steps of spin-coating photoresist and applying photolithographic process to define the spacers.

12. The method as claimed in claim 1, wherein the planarizing step comprises the step of polishing.

13. The method as claimed in claim 12, wherein the polishing step comprises the step(s) of performing a chemical mechanical polishing (CMP).

14. The method as claimed in claim 1, wherein the color filter forming step forms a color filter that comprises color portions that are uneven, and the planarizing step comprises planarizing the color portions to obtain an even surface.

15. The method as claimed in claim 14, wherein the colored portions extend over underlying structures on the substrate, thereby causing unevenness in the colored portions.

16. The method as claimed in claim 15, further comprising the step of forming light blocking portions adjacent to colored portions on the substrate, wherein the underlying structures comprise the light blocking portions, and wherein the colored portions extends over the light blocking portions.

17. The method as claimed in claim 16, wherein the light blocking portions is formed prior to forming the adjacent colored portions.

18. The method as claimed in claim 16, wherein the planarizing step does not expose the underlying light blocking portions.

19. A color filter fabricated in accordance with the method of claim 1.

20. A method of fabricating a liquid crystal display panel, comprising the steps of:
forming a color filter substrate using the method of claim 1;
providing a liquid crystal display element;
providing an array substrate; and
assembling the color filter substrate and the array substrate with liquid crystal layer therebetween.

21. A liquid crystal display panel fabricated in accordance with the method of claim 20.

22. A liquid crystal display device, comprising:
a liquid crystal display panel of claim 21; and
a controller coupled to the liquid crystal display panel to control the liquid crystal display panel to render an image in accordance with an input.

23. An electronic device, comprising:
a liquid crystal display device of claim 22; and
input device coupled to the controller of the liquid crystal display to render an image.
